(19) United States
(12) Patent Application Publication
(10) Pub. No.: US 2026/0262316 A1
(43) Pub. Date: Sep. 3, 2026

(54) IMAGING ELEMENT AND ELECTRONIC APPARATUS

(71) Applicant: Sony Semiconductor Solutions Corporation, Kanagawa (JP)

(72) Inventors: Hideki Haji, Kanagawa (JP); Kenta Ono, Fukuoka (JP)

(73) Assignee: Sony Semiconductor Solutions Corporation, Kanagawa (JP)

(21) Appl. No.: 18/871,336

(22) PCT Filed: May 29, 2023
(86) PCT No.: PCT/JP2023/019854

§ 371 Date: Dec. 3, 2024

(30) Foreign Application Priority Data
Jun. 10, 2022 (JP) 2022-094466
Dec. 19, 2022 (JP) 2022-202458

(51) Int. Cl. H10F 39/00; H04N 25/772; H04N 25/79

(52) U.S. Cl. CPC H10F 39/809; H04N 25/772; H04N 25/79; H10F 39/811

(57) ABSTRACT

A light detecting device includes a first substrate, a second substrate, a third substrate, a first coupling section, and a second coupling section. The first substrate includes a plurality of photoelectric converters. The second substrate includes a first signal processor configured to perform first signal processing, and the second substrate is stacked on the first substrate. The third substrate includes a second signal processor configured to perform second signal processing and the third substrate is stacked on the second substrate. The first coupling section includes a plurality of first electrodes each coupling circuitry of the second substrate and circuitry of the third substrate. The second coupling section includes a plurality of second electrodes each coupling the circuitry of the second substrate and circuitry of the third substrate. An area of the first coupling section is different from an area of the second coupling section, in a plan view.

### CROSS REFERENCE TO RELATED APPLICATIONS

This application claims the benefit of Japanese Priority Patent Application JP 2022-094466 filed on Jun. 10, 2022, and the benefit of Japanese Priority Patent Application JP 2022-202458 filed on Dec. 19, 2022, the entire contents of each which are incorporated herein by reference.

### TECHNICAL FIELD

The present disclosure relates an imaging element and an electronic apparatus.

### BACKGROUND ART

Some conventional imaging elements include a pixel array section, an AD converter, and a memory section.

### CITATION LIST

### Patent Literature

PTL 1: International Publication No. WO2014/007004

### SUMMARY

### Technical Problem

In an imaging element, it is desired to suppresses an increase in chip area. It is desirable to provide an imaging element that makes it possible to suppress an increase in chip area.

According to aspects of the disclosure, there is provided a light detecting device comprising a first substrate including a plurality of photoelectric converters, the plurality of photoelectric converters configured to generate electric charges by photo-electric conversion, a second substrate including a first signal processor configured to perform first signal processing to generate a signal based on the electric charges generated by the plurality of photoelectric converters, the second substrate stacked on the first substrate, a third substrate including a second signal processor configured to perform second signal processing, the third substrate stacked on the second substrate, a first coupling section including a plurality of first electrodes, the plurality of first electrodes coupling circuitry of the second substrate and circuitry of the third substrate, and a second coupling section including a plurality of second electrodes, the plurality of second electrodes coupling the circuitry of the second substrate and circuitry of the third substrate, an area of the first coupling section being different from an area of the second coupling section in a plan view.

In some embodiments, the plurality of photoelectric converters is arranged on the first substrate in a first direction and a second direction orthogonal to the first direction. In some embodiments, the plurality of first electrodes is arranged side by side in a first direction and the plurality of second electrodes is arranged side by side in the first direction. In some embodiments, a length of the first coupling section in the first direction is different from a length of the second coupling section in the first direction. In some embodiments, at least a portion of the first signal processor is arranged between the first coupling section and the second coupling section in the plan view. In some embodiments, the first substrate includes a plurality of pixels, each pixel of the plurality of pixels including a photoelectric converter of the plurality of photoelectric converters and configured to output an analog signal based on the electric charges generated by photoelectric conversion and the second substrate includes an analog-digital converter configured to convert the analog signal outputted from the pixel into a digital signal. In some embodiments, the first signal processor is configured to perform the first signal processing to generate a first digital signal based on the electric charges generated by the plurality of photoelectric converters and the second signal processor is configured to perform the second signal processing to generate a second digital signal based on a signal from the first coupling section, the signal based on the electric charges generated by the plurality of photoelectric converters. In some embodiments, the first coupling section is arranged between the analog-digital converter and the first signal processor in the plan view. In some embodiments, the second coupling section is arranged on side opposite to the first coupling section with respect to the first signal processor in the plan view. In some embodiments, the plurality of first electrodes is arranged in two or more rows. In some embodiments, the light detecting device further comprises a compression section arranged on the second substrate and configured to compress a signal and a decompression section arranged on the third substrate and configured to decompress the compressed signal, wherein the first coupling section is configured to transmit the compressed signal compressed by the compression section to the decompression section. In some embodiments, the compression section is arranged between the analog-digital converter and the first signal processor. In some embodiments, the light detecting device further comprises a third signal processor arranged on the third substrate, wherein the third signal processor is configured to perform third signal processing to generate a third digital signal based on the electric charges generated by the plurality of photoelectric converters through the second coupling section. In some embodiments, the third signal processor is configured to perform recognition processing on a basis of the third digital signal. In some embodiments, the first coupling section is arranged between the second signal processor and the third signal processor in the plan view. In some embodiments, the second coupling section is arranged on a side opposite to the first coupling section with respect to the third signal processor in the plan view. In some embodiments, the second coupling section includes at least one of a first converter or a second converter, the first converter configured to convert a serial signal into a parallel signal, and the second converter configured to convert a parallel signal into a serial signal. In some embodiments, the light detecting device further comprises an interface section, the interface section arranged on the second substrate and configured to output from the light detecting device at least one of a signal outputted from the first signal processor or a signal outputted from the second signal processor, wherein the second coupling section is arranged between the first signal processor and the interface section in the plan view. In some embodiments, each first electrode of the plurality of first electrodes and each second electrode of the plurality of second electrodes includes a through electrode, a first junction electrode, and a second junction electrode, the through electrode penetrating through the second substrate, the first junction electrode being coupled to the through electrode, and the second junction electrode being coupled to the first junction electrode.

According to aspects of the disclosure, there is provided an electronic apparatus comprising a first substrate including a plurality of photoelectric converters, the plurality of photoelectric converters configured to generate electric charges by photo-electric conversion, a second substrate including a first signal processor configured to perform first signal processing to generate a signal based on the electric charges generated by the plurality of photoelectric converters, is the second substrate stacked on the first substrate, a third substrate including a second signal processor configured to perform second signal processing, the third substrate stacked on the second substrate, a first coupling section including a plurality of first electrodes, the plurality of first electrodes coupling circuitry of the second substrate and circuitry of the third substrate, and a second coupling section including a plurality of second electrodes, the plurality of second electrodes coupling the circuitry of the second substrate and circuitry of the third substrate, an area of the first coupling section being different from an area of the second coupling section in a plan view.

An imaging element according to an embodiment of the present disclosure includes a first substrate, a second substrate, a third substrate, a first coupling section, and a second coupling section. The first substrate includes a plurality of photoelectric converters each configured to generate electric charge by photoelectric conversion. The second substrate includes a first signal processor configured to obtain a signal based on the electric charge generated by the photoelectric converter and perform signal processing, and is stacked on the first substrate. The third substrate includes a second signal processor configured to perform signal processing and is stacked on the second substrate. The first coupling section is provided with a plurality of first electrodes that each couples a circuit of the second substrate and a circuit of the third substrate. The second coupling section is provided with a plurality of second electrodes that each couples the circuit of the second substrate and the circuit of the third substrate. A size of the first coupling section is different from a size of the second coupling section.

An electronic apparatus according to an embodiment of the present disclosure includes a first substrate, a second substrate, a third substrate, a first coupling section, and a second coupling section. The first substrate includes a plurality of photoelectric converters each configured to generate electric charge by photoelectric conversion. The second substrate includes a first signal processor configured to obtain a signal based on the electric charge generated by the photoelectric converter and perform signal processing, and is stacked on the first substrate. The third substrate includes a second signal processor configured to perform signal processing and is stacked on the second substrate. The first coupling section is provided with a plurality of first electrodes that each couples a circuit of the second substrate and a circuit of the third substrate. The second coupling section is provided with a plurality of second electrodes that each couples the circuit of the second substrate and the circuit of the third substrate. A size of the first coupling section is different from a size of the second coupling section.

### BRIEF DESCRIPTION OF DRAWINGS

FIG. 1 is a diagram illustrating an example of a schematic configuration of an electronic apparatus according to an embodiment of the present disclosure.

FIG. 2 is a diagram illustrating an example of a schematic configuration of an imaging element according to the embodiment of the present disclosure.

FIG. 3 is a diagram illustrating a configuration example of the imaging element according to the embodiment of the present disclosure.

FIG. 4 is a diagram illustrating a configuration example of a pixel of the imaging element according to the embodiment of the present disclosure.

FIG. 5 is a schematic view of an example of a cross-sectional configuration of the imaging element according to the embodiment of the present disclosure.

FIG. 6 is a diagram illustrating a configuration example of the imaging element according to the embodiment of the present disclosure.

FIG. 7A is a diagram illustrating a layout example of the imaging element according to the embodiment of the present disclosure.

FIG. 7B is a diagram illustrating a layout example of the imaging element according to the embodiment of the present disclosure.

FIG. 7C is a diagram illustrating a layout example of the imaging element according to the embodiment of the present disclosure.

FIG. 8 is a diagram for description of an example of signal transmission in the imaging element according to the embodiment of the present disclosure.

FIG. 9 is a diagram for description of an example of signal transmission in the imaging element according to the embodiment of the present disclosure.

FIG. 10 is a diagram for description of a configuration example of a first coupling section of the imaging element according to the embodiment of the present disclosure.

FIG. 11 is a diagram illustrating an example of timing adjustment in the first coupling section of the imaging element according to the embodiment of the present disclosure.

FIG. 12A is a diagram illustrating a configuration example of the first coupling section of the imaging element according to the embodiment of the present disclosure.

FIG. 12B is a diagram illustrating a configuration example of a first coupling section of an imaging element according to a comparative example.

FIG. 13 is a diagram for description of a configuration example of an imaging element according to Modification Example 1 of the present disclosure.

FIG. 14 is a diagram for description of a configuration example of a first coupling section of an imaging element according to Modification Example 2 of the present disclosure.

FIG. 15A is a diagram illustrating a layout example of an imaging element according to Modification Example 3 of the present disclosure.

FIG. 15B is a diagram illustrating a layout example of the imaging element according to Modification Example 3 of the present disclosure.

FIG. 16 is a diagram for description of a configuration example of a first coupling section of an imaging element according to Modification Example 4 of the present disclosure.

FIG. 17 is a diagram for description of a configuration example of an imaging element according to Modification Example 5 of the present disclosure.

FIG. 18A is a diagram for description of a configuration example of a first coupling section of the imaging element according to Modification Example 5 of the present disclosure.

FIG. 18B is a timing chart for description of an operation example of the first coupling section of the imaging element according to Modification Example 5 of the present disclosure.

### DESCRIPTION OF EMBODIMENTS

In the following, description is given of embodiments of the present disclosure in detail with reference to the drawings. It is to be noted that the description is given in the following order.
1. Embodiment
2. Modification Examples
3. Usage Examples
4. Application Examples

An imaging element (also called a light detecting device herein) may have a three-layer stacked structure that is a structure in which a first chip provided with a pixel array section, a second chip provided with an AD converter, and a third chip provided with a memory section are stacked (see PTL 1).

### 1. Embodiment

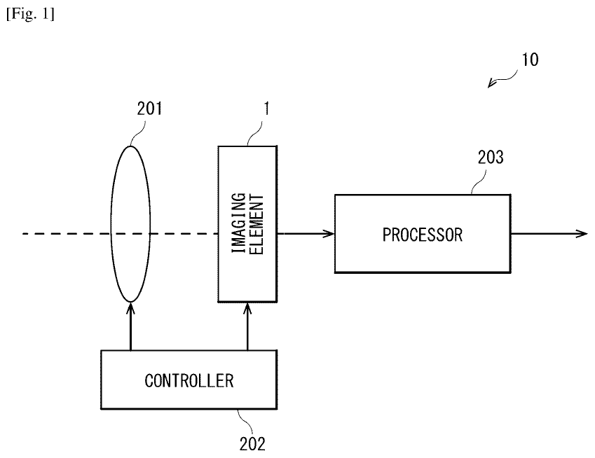

FIG. 1 is a diagram illustrating an example of a schematic configuration of an electronic apparatus according to an embodiment of the present disclosure. An electronic apparatus 10 includes an imaging element 1, an optical system 201, a controller 202, and a processor 203. The optical system 201 includes an optical lens, and guides light from a subject to the imaging element 1.

The imaging element 1 includes a plurality of pixels each including a light-receiving element, and is configured to perform photoelectric conversion of incident light to generate a signal. The light-receiving element (light-receiving section) may convert incident light into electric charge. The imaging element 1 includes, for example, a CMOS (Complementary Metal Oxide Semiconductor) image sensor. The imaging element 1 captures incident light (image light) from a subject through the optical system 201. The imaging element 1 captures an image of the subject formed by the optical lens. The imaging element 1 performs photoelectric conversion of received light to generate a pixel signal.

The controller 202 is configured to be able to control an operation of the imaging element 1. The controller 202 supplies a control signal to the imaging element 1 to control the imaging element 1, and causes the imaging element 1 to output a signal of each of the pixels. The processor 203 includes a signal processor, and is configured to perform signal processing on the signal outputted from the imaging element 1. The controller 202 and the processor 203 each include, for example, a processor and a memory (such as a ROM or a RAM), and perform signal processing (information processing) on the basis of a program. The processor 203 may perform various types of signal processing on the signal of each of the pixels outputted from the imaging element 1, and output pixel data.

### Schematic Configuration of Imaging Element

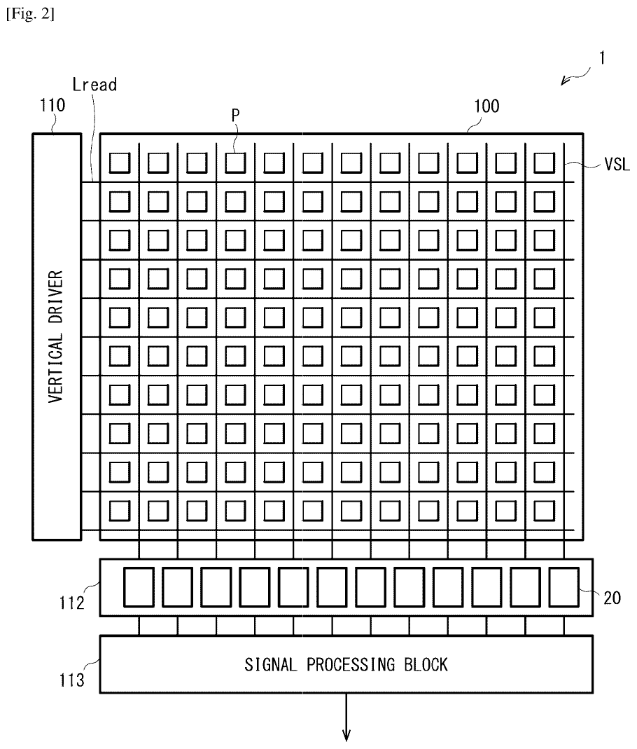

FIG. 2 is a diagram illustrating an example of a schematic configuration of an imaging element according to the embodiment. In an example illustrated in FIG. 2, the imaging element 1 has, as an imaging region, a region (pixel section 100) where a plurality of pixels P is two-dimensionally arranged in a matrix. The light-receiving element (light-receiving section) of each of the pixels P includes a photoelectric converter that is able to generate electric charge by photoelectric conversion. The photoelectric converter includes, for example, a photodiode, and is configured to be able to perform photoelectric conversion of light. As in the example illustrated in FIG. 2, the imaging element 1 includes, for example, a vertical driver 110, a column signal processor 112, a signal processing block 113, and the like, in a region around the pixel section 100.

The imaging element 1 is provided with, for example, a plurality of pixel drive lines Lread and a plurality of vertical signal lines VSL. For example, the pixel section 100 is wired with the plurality of pixel drive lines Lread for respective pixel rows each including a plurality of pixels P disposed side by side in a horizontal direction (row direction). In addition, the pixel section 100 is wired with the vertical signal lines VSL for respective pixel columns each including a plurality of pixels P disposed side by side in a vertical direction (column direction). The pixel drive lines Lread each are configured to transmit a drive signal for signal reading from the pixel P. The vertical signal lines VSL each are a signal line that is able to transmit a signal from the pixel P. The vertical signal lines VSL each are configured to transmit a signal outputted from the pixel P.

The vertical driver 110 includes a shift register, an address decoder, and the like. The vertical driver 100 is configured to drive each of the pixels P in the pixel section 100. The vertical driver 110 includes a pixel driver, and generates a signal for driving the pixel P, and outputs the signal to each of the pixels P in the pixel section 100 through the pixel drive line Lread. The vertical driver 110 generates, for example, a signal for controlling a transfer transistor, a signal for controlling a reset transistor, and the like, and supplies the signals to each of the pixels P through the pixel drive line Lread.

The signal outputted from each of the pixels P selected and scanned by the vertical driver 110 is supplied to the column signal processor 112 through the vertical signal line VSL. The column signal processor 112 is configured to perform signal processing on an inputted signal of each of the pixels. The column signal processor 112 includes, for example, a load circuit section, an AD (Analog-Digital) converter 20, a horizontal selection switch, and the like. The signal of each of the pixels P transmitted through a corresponding one of the vertical signal lines VSL is subjected to signal processing by the column signal processor 112, and is outputted to the signal processing block 113.

The signal processing block 113 is configured to perform signal processing on an inputted signal and output the signal. The signal processing block 113 is configured to be able to obtain the signal of each of the pixels converted into a digital signal from the column signal processor 112 and execute signal processing. The signal processing block 113 is also referred to as a logic circuit section (digital circuit section) that is able to perform digital signal processing.

The signal processing block 113 may perform signal processing on the signals of the pixels sequentially inputted from the column signal processor 112 and output the signals having been subjected to the processing. As described later, the signal processing block 113 includes a plurality of signal processors (signal processing circuits). The signal processing block 113 may perform, for example, various types of digital signal processing such as noise reduction processing (e.g., black level adjustment, column variation correction, or the like) and interpolation processing.

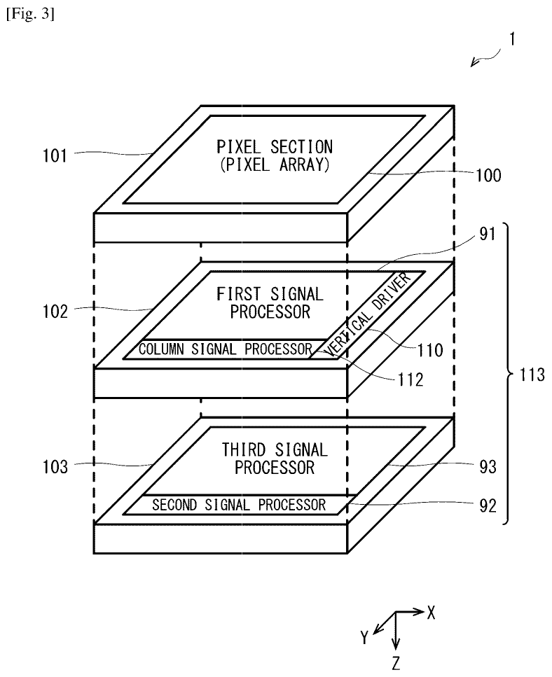

FIG. 3 is a diagram illustrating a configuration example of the imaging element according to the embodiment. As illustrated in FIG. 3, the imaging element 1 includes a first substrate 101, a second substrate 102, and a third substrate 103. The first substrate 101, the second substrate 102, and the third substrate 103 are stacked on top of each other. The imaging element 1 has a structure (stacked structure) in which the first substrate 101, the second substrate 102, and the third substrate 103 are stacked in a Z-axis direction. It is to be noted that, as illustrated in FIG. 3, an incidence direction of light from the subject is defined as the Z-axis direction, a left/right direction of the diagram orthogonal to the Z-axis direction is defined as an X-axis direction, and a direction orthogonal to the Z-axis direction and the X-axis direction is defined as a Y-axis direction. In the following diagrams, a direction may be expressed with reference to a direction of an arrow in FIG. 3 in some cases.

Each substrate may include circuitry, such as one or more of the various circuits described herein. The first substrate 101 is provided with the pixel section 100. In the pixel section 100, the plurality of pixels P are disposed in the horizontal direction (row direction) that is a first direction, and the vertical direction (column direction) that is a second direction orthogonal to the first direction. The pixel section 100 includes a pixel array in which the pixels P are disposed in a matrix. The second substrate 102 is provided with the vertical driver 110 and the column signal processor 112. In addition, in the present embodiment, the signal processing block 113 includes a plurality of logic circuits, and is provided dividedly on a plurality of substrates.

As in an example illustrated in FIG. 3, the signal processing block 113 includes a first signal processor 91, a second signal processor 92, and a third signal processor 93, and is disposed dividedly on the second substrate 102 and the third substrate 103. In the example illustrated in FIG. 3, the first signal processor 91 is disposed on the second substrate 102. The second signal processor 92 and the third signal processor 93 are disposed on the third substrate 103. Disposing the signal processing block 113 dividedly on a plurality of substrates makes it possible to suppress an increase in chip area. It is possible to dispose a plurality of circuits or the like that is able to perform processing on signals from the pixels P while suppressing an increase in chip area.

### Configuration of Pixel

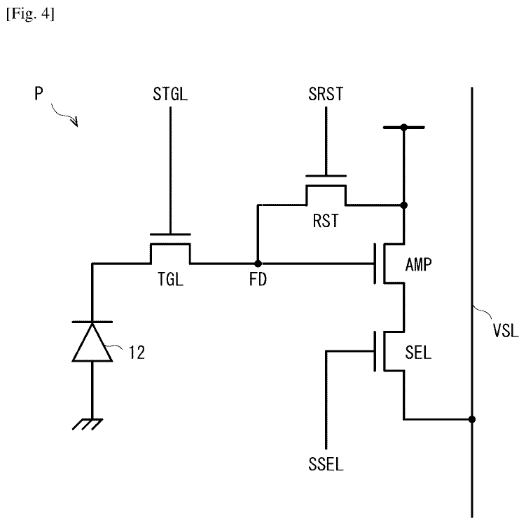

FIG. 4 is a diagram illustrating a configuration example of the pixel of the imaging element according to the embodiment. The pixels P each include a photoelectric converter 12, a transistor TGL, a floating diffusion (FD), a transistor AMP, a transistor SEL, and a transistor RST.

Each of the transistor TGL, the transistor AMP, the transistor SEL, and the transistor RST includes a MOS transistor (MOSFET) having terminals including a gate, a source, and a drain. In an example illustrated in FIG. 4, each of the transistors TGL, AMP, SEL, and RST includes a NMOS transistor. It is to be noted that the transistors of the pixel P may each include a PMOS transistor.

The photoelectric converter 12 is configured to be able to generate electric charge by photoelectric conversion. In the example illustrated in FIG. 4, the photoelectric converter 12 includes a photodiode (PD), and converts incident light into electric charge. The photoelectric converter 12 performs photoelectric conversion to generate electric charge corresponding to an amount of received light.

The transistor TGL is configured to be able to transfer, to the FD, the electric charge generated by photoelectric conversion by the photoelectric converter 12. As illustrated in FIG. 4, the transistor TGL is controlled by a signal STGL to electrically couple the photoelectric converter 12 and the FD or break electrical coupling between the photo-electric converter 12 and the FD. The transistor TGL is a transfer transistor, and may transfer, to the FD, electric charge generated by photoelectric conversion by the photo-electric converter 12 and stored.

The FD is an electric charge storage section, and is configured to be able to store the transferred electric charge. The FD may store the electric charge generated by the photoelectric conversion by the photoelectric converter 12. The FD is also referred to as a holding section that is able to hold the transferred electric charge. The FD stores the transferred electric charge, and converts the electric charge into a voltage corresponding to a capacitance of the FD.

The transistor AMP is configured to generate and output a signal based on the electric charge stored in the FD. As illustrated in FIG. 4, the gate of the transistor AMP is electrically coupled to the FD, and the voltage obtained by conversion by the FD is inputted to the gate of the transistor AMP. The drain of the transistor AMP is coupled to a power supply line that is to be supplied with a power supply voltage, and the source of the transistor AMP is coupled to the vertical signal line VSL though the transistor SEL. The transistor AMP is an amplification transistor, and may generate a signal based on the electric charge stored in the FD, that is, a signal based on the voltage of the FD and output the signal to the vertical signal line VSL.

The transistor SEL is configured to be able to control output of the signal of the pixel. The transistor SEL is configured to be able to output a signal from the transistor AMP to the vertical signal line VSL by being controlled by a signal SSEL. The transistor SEL is a selection transistor, and may control an output timing of the signal of the pixel. It is to be noted that the transistor SEL may be provided between the power supply line that is to be supplied with the power supply voltage, and the transistor AMP. Alternatively, the transistor SEL may be omitted as necessary.

The transistor RST is configured to be able to reset the voltage of the FD. In the example illustrated in FIG. 4, the transistor RST is electrically coupled to the power supply line, and is configured to reset electric charge of the pixel P. The transistor RST may reset the electric charge stored in the FD and reset the voltage of the FD by being controlled by a signal SRST. It is to be noted that the transistor RST may discharge electric charge stored in the photoelectric converter 12 through the transistor TGL. The transistor RST is a reset transistor.

The vertical driver 110 (see FIGS. 2 and 3) supplies a drive signal to each of the gates of the transistor TGL, the transistor SEL, the transistor RST, and the like of each pixel P to turn the transistors to an ON state (conduction state) or an OFF state (non-conduction state). The transistor TGL, the transistor SEL, and the like are controlled by the vertical driver 110 to be turned on or off. The vertical driver 110 controls the signal STGL, the signal SSEL, the signal SRST, and the like that are to be inputted to each pixel P, thereby outputting a signal from the transistor AMP of each pixel P to the vertical signal line VSL.

The signal of each of the pixels is outputted to the column signal processor 112 through the vertical signal line VSL. As described above, the column signal processor 112 includes the load circuit section (not illustrated), the AD converter 20, and the like. The load circuit section is coupled to the vertical signal line VSL. The load circuit section includes, for example, a current source that is able to supply a current to the transistor AMP of the each of the pixel P. The load circuit section configures a source-follower circuit together with the transistor AMP of the pixel P. It is to be noted that the column signal processor 112 may include an amplification circuit section that is configured to amplify a signal read from the pixel P through the vertical signal line VSL.

The AD converter 20 is configured to convert an inputted analog signal into a digital signal. The AD converter 20 is an ADC (Analog to Digital Converter). The AD converter 20 is provided for each of the plurality of vertical signal lines VSL. The AD converter 20 (AD conversion circuit) is provided for each pixel column including a plurality of pixels P disposed side by side in the vertical direction (column direction). The AD converter 20 performs AD conversion processing on the signal of each of the pixels that is an analog signal inputted from each of the pixels P through the vertical signal line VSL. In one example, the AD converter 20 includes a comparator (comparator circuit) and a counter, and converts the inputted signal of each of the pixels into a digital signal having a predetermined bit number. The column signal processor 112 outputs a pixel signal having been subjected to AD conversion to the signal processing block 113.

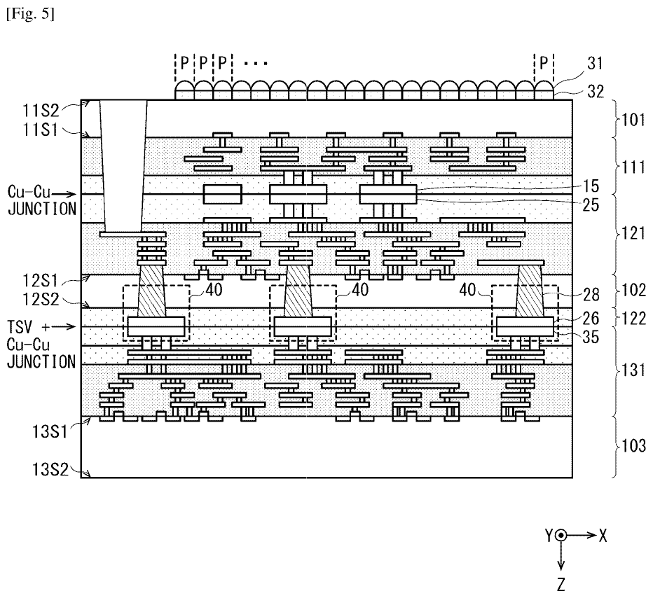

FIG. 5 is a schematic view of an example of a cross-sectional configuration of the imaging element according to the embodiment. The imaging element 1 has a configuration in which the first substrate 101, the second substrate 102, and the third substrate 103 are stacked in the Z-axis direction. The first substrate 101, the second substrate 102, and the third substrate 103 each include a semiconductor substrate (e.g., a silicon substrate).

The first substrate 101, the second substrate 102, and the third substrate 103 respectively has first surfaces 11S1, 12S1, and 13S1 each provided with a transistor, and second surfaces 11S2, 12S2, and 13S2, as illustrated in FIG. 5. The first surfaces 11S1, 12S1, and 13S1 each are an element formation surface where an element such as a transistor is formed. Each of the first surfaces 11S1, 12S1, and 13S1 is provided with a gate electrode, a gate oxide film, and the like. It is to be noted that a lens section 31 that condenses light, a color filter 32, and the like are provided for each pixel P on side of the second surface 11S2 of the first substrate 101.

As illustrated in FIG. 5, the first surface 11S1 of the first substrate 101 is provided with a wiring layer 111. In addition, the first surface 12S1 of the second substrate 102 is provided with a wiring layer 121, and the second surface 12S2 of the second substrate 102 is provided with a wiring layer 122. The first surface 13S1 of the third substrate 103 is provided with a wiring layer 131. The wiring layers 111, 121, 122, and 131 each include, for example, a conductor film and an insulating film, and have a plurality of wiring lines, a via, and the like. The wiring layers 111, 121, 122, and 131 each include, for example, two or more layers of wiring lines.

The wiring layers 111, 121, 122, and 131 has a configuration in which a plurality of wiring lines is stacked with an interlayer insulating layer (interlayer insulating film) interposed therebetween. Each of the wiring layers is formed using, for example, aluminum (Al), copper (Cu), tungsten (W), polysilicon (Poly-Si), or the like. The interlayer insulating layer is formed using, for example, a monolayer film including one of silicon oxide (SiO), silicon nitride (SIN), silicon oxynitride (SiON), and the like, or a stacked film including two or more thereof.

It is to be noted that the first substrate 101 and the wiring layer 111 may be referred to collectively as the first substrate 101 (or a first circuit layer). In addition, the second substrate 102 and the wiring layers 121 and 122 may be referred to collectively as the second substrate 102 (or a second circuit layer). The third substrate 103 and the wiring layer 131 may be referred to collectively as the third substrate 103 (or a third circuit layer).

The first substrate 101 and the second substrate 102 are stacked by joining electrodes with the first surface 11S1 and the first surface 12S1 opposed to each other. Elements such as transistors are formed on the first surface 11S1 and the first surface 12S1. In other words, the first substrate 101 and the second substrate 102 are joined with respective front surfaces opposed to each other.

The second substrate 102 and the third substrate 103 are stacked by joining electrodes with the second surface 12S2 and the first surface 13S1 opposed to each other. Elements such as transistors are formed on the first surface 13S1. In other words, the second substrate 102 and the third substrate 103 are joined with a back surface of the second substrate 102 and a front surface of the third substrate 103 opposed to each other.

In one example, the first surface 11S1 of the first substrate 101 and the first surface 12S1 of the second substrate 102 are bonded together by joining metal electrodes each including copper (Cu), that is, a Cu—Cu junction. In addition, the second surface 12S2 of the second substrate 102 and the first surface 13S1 of the third substrate 103 are also bonded by a Cu—Cu junction, for example. It is to be noted that the electrodes used for junction may include, for example, a metal material such as nickel (Ni), cobalt (Co), or tin (Sn) other than copper (Cu), or may include another material.

In an example illustrated in FIG. 5, a plurality of electrodes 15 each including an uppermost wiring line in the wiring layer 111 and a plurality of electrodes 25 each including an uppermost wiring line in the wiring layer 121 are joined to couple the first substrate 101 and the second substrate 102. The electrodes 15 and 25 each are a junction electrode. In addition, a plurality of electrodes 26 each including an uppermost wiring line in the wiring layer 122 and a plurality of electrodes 35 each including an uppermost wiring line in the wiring layer 131 are joined to couple the second substrate 102 to the third substrate 103. The electrodes 26 and 35 each are a junction electrode.

The second substrate 102 and the wiring layers 121 and 122 include a plurality of through electrodes 28, as schematically illustrated in FIG. 5. The through electrodes 28 are electrodes penetrating through the second substrate 102. The through electrodes 28 are formed to extend in the Z-axis direction and reach the wiring layer 122 of the second substrate 102. The through electrodes 28 each include, for example, tungsten (W), aluminum (Al), cobalt (Co), molybdenum (Mo), ruthenium (Ru), or the like. It is to be noted that the through electrodes 28 may each include another metal material.

In the imaging element 1 according to the present embodiment, a circuit provided on side of the first surface 12S1 of the second substrate 102, a circuit provided on side of the first surface 13S1 of the third substrata 103 are electrically coupled by the through electrodes 28 and the electrodes 26 and 35 for junction. The through electrode 28 and the electrodes 26 and 35 for junction configure an electrode (coupling electrode 40) that couples the circuit of the second substrate 102 and the circuit of the third substrate 103, and are configured to be able to transmit a signal. The coupling electrode 40 couples circuits provided in different layers.

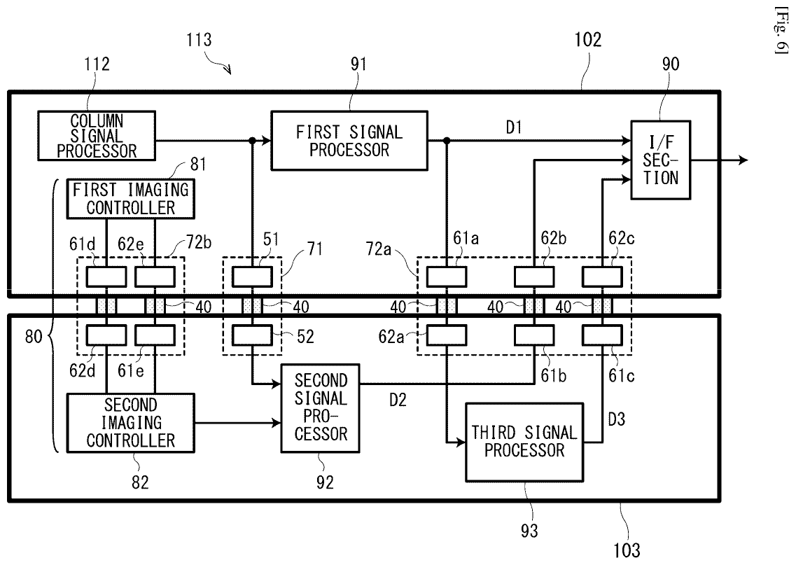

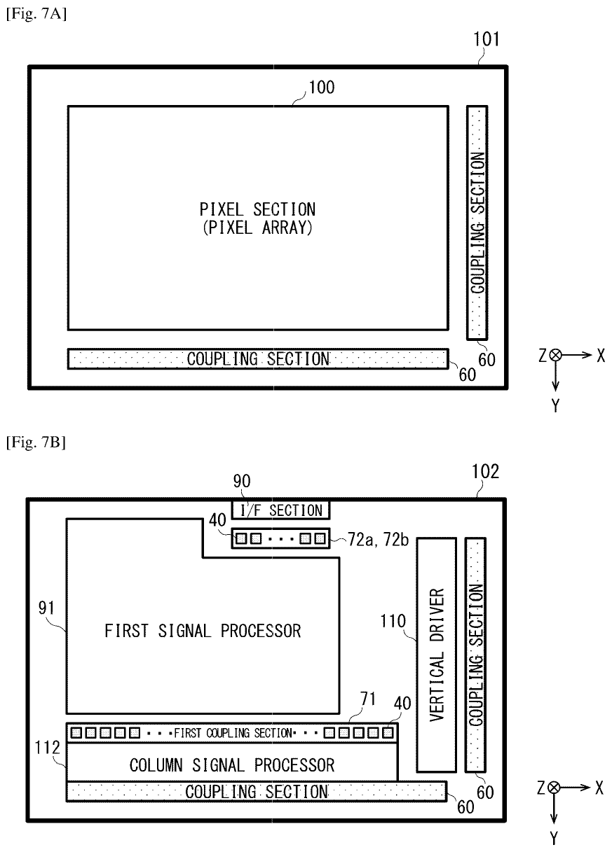

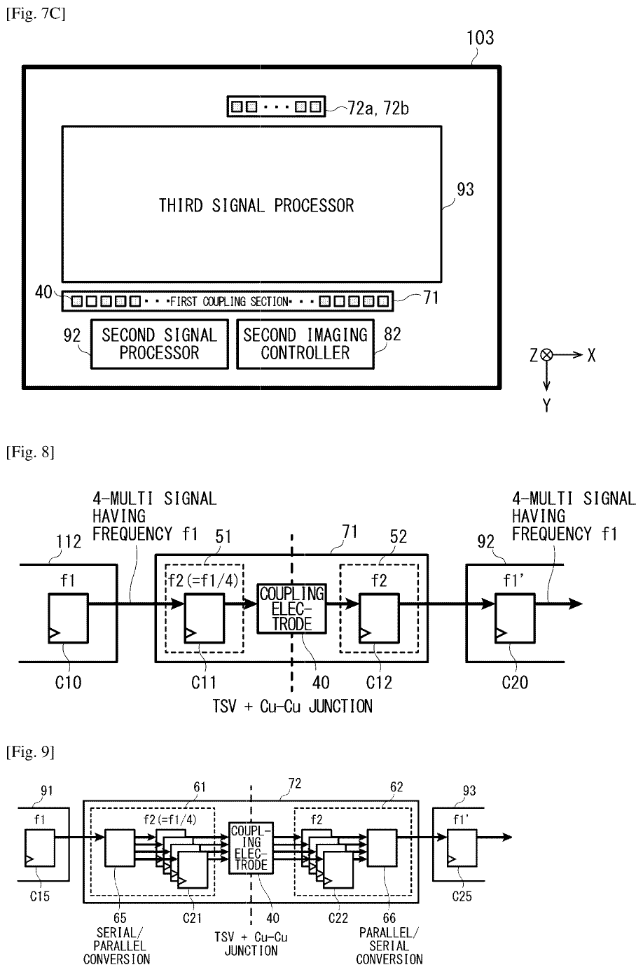

In addition, in the imaging element 1, a circuit provided on side of the first surface 11S1 of the first substrate 101 and the circuit provided on side of the first surface 12S1 of the second substrate 102 are electrically coupled by the electrodes 15 and 25 for junction. The circuit on side of the first surface 11S1 of the first substrate 101 and the circuit on side of the first surface 12S1 of the second substrate 102 are electrically coupled by a coupling section 60 (see FIGS. 7A and 7B to be described later). The coupling section 60 includes a plurality of electrodes 15 and a plurality of electrodes 25 for junction, and electrically couples the circuit of the first substrate 101 and the circuit of the second substrate 102. The coupling section 60 may include a through electrode, a via, or the like. The circuit of the first substrate 101 and the circuit of the second substrate 102 are coupled by a Cu-Cu junction, a through electrode, a via, or the like.

FIG. 6 is a diagram illustrating a configuration example of the imaging element according to the embodiment. FIG. 6 illustrates the column signal processor 112 and the signal processing block 113 of the imaging element 1. As illustrated in FIG. 6, the signal processing block 113 includes the first signal processor 91, the second signal processor 92, the third signal processor 93, an imaging controller 80, and an interface section 90 (I/F section). The imaging controller 80 includes a first imaging controller 81 and a second imaging controller 82. For example, the first signal processor 91, the first imaging controller 81, the interface section 90, and the like are disposed on the second substrate 102. In addition, the second signal processor 92, the third signal processor 93, the second imaging controller 82, and the like may be disposed on the third substrate 103.

In addition, the signal processing block 113 of the imaging element 1 includes a first coupling section 71, and a second coupling section 72 (a second coupling section 72a and a second coupling section 72b in FIG. 7). Each of the first coupling section 71 and the second coupling section 72 is provided with a plurality of electrodes 40 (the through electrodes 28 and the electrodes 26 and 35) described above. The first coupling section 71 and the second coupling section 72 each couple the circuit of the second substrate 102 and the circuit of the third substrate 103.

The first signal processor 91 is configured to be able to obtain the signal of each of the pixels and perform signal processing. In an example illustrated in FIG. 6, the first signal processor 91 obtains, from the column signal processor 112, a pixel signal converted into a digital signal. A digital signal based on electric charge generated by the photoelectric converter 12 of the pixel P is inputted as a pixel signal to the first signal processor 91.

The first signal processor 91 includes a circuit that performs various types of signal processing on the pixel signal. The first signal processor 91 includes an operation circuit, a memory circuit, and the like. The first signal processor 91 may perform signal processing such as noise reduction processing, interpolation processing (remosaic processing), or grayscale correction processing on, for example, the pixel signal having been subjected to AD conversion. The first signal processor 91 may perform various types of signal processing on the signal of each of the pixels to generate image data D1 (image signal). The first signal processor 91 may output the image data D1, which is obtained by processing on the signal from the column signal processor 112, to the interface section 90, the second coupling section 72a, and the like.

The first coupling section 71 includes a plurality of coupling electrodes 40, and couples the circuit of the second substrate 102 and the circuit of the third substrate 103. In the example illustrated in FIG. 6, the first coupling section 71 electrically couples the column signal processor 112 and the first signal processor 91 included in the circuit of the second substrate 102 and the second signal processor 92 included in the circuit of the third substrate 103.

The first coupling section 71 includes a plurality of first output sections 51 and a plurality of first input sections 52, and is configured to be able to transmit a signal. The first output sections 51 are provided on the second substrate 102, and the first input sections 52 are provided on the third substrate 103. The first output sections 51 are output sections (output circuits) that each output a signal to the circuit of the third substrate 103. The first input sections 52 are input sections (input circuits) to which a signal is inputted from the circuit of the second substrate 102. The first output sections 51 and the first input sections 52 are also referred to as transmission sections that are able to transmit a signal.

The first coupling section 71 includes a plurality of coupling electrodes 40, a plurality of first output sections 51, and a plurality of first input sections 52 corresponding to the number of signals to be transmitted (such as a data amount). The first output sections 51 and the first input sections 52 of the first coupling section 71 each include, for example, a flip-flop (FF circuit), an inverter (INV circuit), and the like.

The first output sections 51 of the first coupling section 71 each are electrically coupled to the column signal processor 112 and the first signal processor 91. The first input sections 52 of the first coupling section 71 each are electrically coupled to the second signal processor 92. A pixel signal converted into a digital signal is inputted from the column signal processor 112 to the first output section 51. The pixel signal inputted to the first output section 51 is transmitted to the first input section 52 through the coupling electrode 40 by the first output section 51. The first coupling section 71 may output the pixel signal from the first input section 52.

The second signal processor 92 is configured to be able o obtain the signal of each of the pixels and performs signal processing. In the example illustrated in FIG. 6, the second signal processor 92 obtains the pixel signal that is a digital signal from the first coupling section 71. A digital signal based on electric charge generated by the photo-electric converter 12 of the pixel P is inputted as a pixel signal to the second signal processor 92.

The second signal processor 92 includes a circuit that performs various types of signal processing on the pixel signal. The second signal processor 92 includes an operation circuit, a memory circuit, and the like. The second signal processor 92 may perform signal processing such as noise reduction processing, interpolation processing, or crop processing on, for example, the pixel signal. The second signal processor 92 may perform various types of signal processing on the signal of each of the pixels to generate image data D2 (image signal). The second signal processor 92 may output the image data D2 to the second coupling section 72a and the like.

The second coupling section 72a includes a plurality of coupling electrodes 40, and couples the circuit of the second substrate 102 and the circuit of the third substrate 103. In the example illustrated in FIG. 6, the second coupling section 72a electrically couples the first signal processor 91 and the third signal processor 93. In addition, the second coupling section 72a electrically couples the second signal processor 92 and the interface section 90, and electrically couples the third signal processor 93 and the interface section 90.

The second coupling section 72a includes a plurality of second output sections 61 and a plurality of second input section 62, and is configured to be able to transmit a signal. The second coupling section 72a includes a plurality of coupling electrodes 40, a plurality of second output sections 61, and a plurality of the second input sections 62 corresponding to the number of signals to be transmitted. The second output sections 61 (second output sections 61a to 61c in FIG. 6) and the second input sections 62 (second input sections 62a to 62c) of the second coupling section 72a each include, for example, a flip-flop, an inverter, and the like. It is to be noted that the second output sections 61 and the second input sections 62 are also referred to as transmission sections that are able to transmit a signal.

In the example in FIG. 6, the second substrate 102 is provided with the second output section 61a, the second input section 62b, and the second input section 62c. In addition, the third substrate 103 is provided with the second input section 62a, the second output section 61b, and the second output section 61c. The second output section 61a is an output section (output circuit) that outputs a signal to the circuit of the third substrate 103, and the second input section 62a is an input section (input circuit) to which a signal is inputted from the circuit of the second substrate 102. The second output sections 61b and 61c each are an output section that outputs a signal to the circuit of the second substrate 102. In addition, the second input sections 62b and 62c each are an input section to which a signal is inputted from the circuit of the third substrate 103.

The second output section 61a of the second coupling section 72a is electrically coupled to the first signal processor 91. The second input section 62a of the second coupling section 72a is electrically coupled to the third signal processor 93. The image data D1 including the pixel of each of the pixels having been subjected to signal processing is inputted from the first signal processor 91 to the second output section 61a. The image data DI inputted to the second output section 61a is transmitted to the second input section 62a through the coupling electrode 40 by the second output section 61a.

The second output section 61b of the second coupling section 72a is electrically coupled to the second signal processor 92. The second input section 62b of the second coupling section 72a is electrically coupled to the interface section 90. Image data D2 including the signal of each of the pixels having been subjected to signal processing is inputted from the second signal processor 92 to the second output section 61b. The image data D2 inputted to the second output section 61b is transmitted to the second input section 62b through the coupling electrode 40 by the second output section 61b.

The third signal processor 93 is configured to be able to obtain the signal of each of the pixels and perform signal processing. In the example illustrated in FIG. 6, the third signal processor 93 obtains the image data D1 that is a digital signal from the first signal processor 91 through the second output section 61a and the second input section 62a of the second coupling section 72a. The image data DI including the signal of each of the pixels having been subjected to signal processing is inputted to the third signal processor 93.

The third signal processor 93 includes a circuit that performs various types of signal processing on the pixel signal. The third signal processor 93 includes an operation circuit, a memory circuit, and the like. The third signal processor 93 includes, for example, a DSP (Digital Signal Processor), an ISP (Image Signal Processor), or the like. The third signal processor 93 may perform recognition processing on the basis of the image data D1 including the signal of each of the pixels. The third signal processor 93 is also referred to as an AI (Artificial Intelligence) circuit.

In one example, the third signal processor 93 performs, on the image data D1 including the signal of each of the pixels, interpolation processing, gain adjustment processing, color adjustment processing, normalization processing, and the like to generate data to be used for recognition processing. The third signal processor 93 performs image recognition processing using a DNN (Deep Neural Network) on the basis of generated data to generate data D3 indicating a recognition result. The data D3 includes, for example, data (signal) indicating a specific subject included in the image data D1. The third signal processor 93 may output the data D3 to the second coupling section 72a.

The second output section 61c of the second coupling section 72a is electrically coupled to the third signal processor 93. The second input section 62c of the second coupling section 72a is electrically coupled to the interface section 90. The data D3 is inputted from the third signal processor 93 to the second output section 61c. The data D3 inputted to the second output section 61c is transmitted to the second input section 62c through the coupling electrode 40 by the second output section 61c.

The interface section 90 includes a transmission circuit, and is configured to be able to transmit an inputted signal. The interface section 90 includes an interface circuit. The image data D1 is inputted from the first signal processor 91 to the interface section 90. In addition, the image data D2 is inputted from the second signal processor 92 to the interface section 90 through the second output section 61b and the second input section 62b of the second coupling section 72a.

In addition, the data D3 is inputted from the third signal processor 93 to the interface section 90 through the second output section 61c and the second input section 62c of the third signal processor 93. The interface section 90 may transmit the image data D1, the image data D2, and the data D3 to outside at high speed. Thus, the imaging element 1 according to the present embodiment is able to generate the image data D1, the image data D2, and the data D3 on the basis of the signal of each of the pixels and output the image data D1, the image data D2, and the data D3 to outside.

The imaging controller 80 is configured to control each component of the imaging element 1. The imaging controller 80 receives a clock supplied from outside or data or the like for commanding an operation mode, and controls each component of the imaging element 1. The imaging controller 80 includes, for example, a processor (e.g., a CPU) and a memory, and performs various types of signal processing. The first imaging controller 81 controls an operation of the circuit of the second substrate 102, e.g., operations of the first signal processor 91 and the like. The second imaging controller 82 controls an operation of the circuit of the third substrate 103, e.g., operations of the second signal processor 92, the third signal processor 93, and the like.

The second coupling section 72b includes a plurality of coupling electrodes 40, and electrically couples the first imaging controller 81 and the second imaging controller 82. The second coupling section 72b is configured to be able to transmit a signal. The second coupling section 72b includes a plurality of coupling electrodes 40, a plurality of second output sections 61, and a plurality of second input sections 62 corresponding to the number of signals to be transmitted. The second output sections 61 (second output sections 61d and 61e in FIG. 6) and the second input sections 62 (second input sections 62d and 62e) of the second coupling section 72b each include, for example, a flip-flop, an inverter, and the like.

The second output section 61d of the second coupling section 72b is electrically coupled to the first imaging controller 81. The second input section 62d of the second coupling section 72b is electrically coupled to the second imaging controller 82. A signal inputted from the first imaging controller 81 to the second output section 61d is transmitted to the second imaging controller 82 through the coupling electrode 40 and the second input section 62d.

The second output section 61e of the second coupling section 72b is electrically coupled to the second imaging controller 82. The second input section 62e of the second coupling section 72b is electrically coupled to the first imaging controller 81. A signal inputted from the second imaging controller 82 to the second output section 61e is transmitted to the first imaging controller 81 through the coupling electrode 40 and the second input section 62e. The first imaging controller 81 and the second imaging controller 82 may transmit and receive a signal by the second coupling section 72b and control each component of the imaging element 1.

FIGS. 7A to 7C are diagrams each illustrating a layout example of the imaging element according to the embodiment. The layout example in FIG. 7A indicates a layout example in the first substrate 101 of the first to third substrates 101 to 103. The layout example in FIG. 7B indicates a layout example in the second substrate 102. In addition, the layout example in FIG. 7C indicates a layout example in the third substrate 103.

In the examples illustrated in FIGS. 7A and 7B, two coupling sections 60 are provided on each of the first substrate 101 and the second substrate 102. On the first substrate 101, two coupling sections 60 are disposed around the pixel section 100. On the second substrate 102, the coupling sections 60 are provided in a region outside the vertical driver 110 and a region outside the column signal processor 112. The coupling sections 60 each include a plurality of electrodes 15 and a plurality of electrodes 25 for junction described above corresponding to the number of signals to be transmitted. The coupling sections 60 each couple the circuit of the first substrate 101 and the circuit of the second substrate 102.

The first coupling section 71 and the second coupling section 72 (second coupling sections 72a and 72b) each include a plurality of coupling electrodes 40 corresponding to the number of signals to be transmitted, as described above. In the first coupling section 71, the plurality of coupling electrodes 40 is provided side by side in the X-axis direction. Also in the second coupling section 72, the plurality of coupling electrodes 40 is provided side by side in the X-axis direction. Various coupling sections may have different areas in a plan view. For example, the first coupling section 71 and the second coupling section 72 have sizes different from each other. That is, a region provided with the first coupling section 71 and a region provided with the second coupling section 72 have widths different from each other.

As schematically illustrated in FIGS. 7B and 7C, the number of coupling electrodes 40 in the first coupling section 71 is larger than the number of coupling electrodes 40 in the second coupling section 72. A size of the first coupling section 71 is larger than a size of the second coupling section 72. A length in the X-axis direction of the first coupling section 71 is larger than a length in the X-axis direction of the second coupling section 72. Accordingly, in the imaging element 1, it is possible to transmit a large number of signals simultaneously (in parallel).

In addition, as illustrated in FIG. 7B, the first coupling section 71 is provided between the column signal processor 112 including a plurality of AD converters 20 and the first signal processor 91 in plan view. The first coupling section 71 is disposed adjacent to the column signal processor 112 and the first signal processor 91. Accordingly, in the imaging element 1 according to the present embodiment, it is possible to efficiently perform signal transmission from the column signal processor 112 to the first signal processor 91 and the first coupling section 71.

In addition, as illustrated in FIG. 7C, the first coupling section 71 is provided between the second signal processor 92 and the third signal processor 93 in plan view. The first coupling section 71 is disposed adjacent to the second signal processor 92. Accordingly, in the imaging element 1, it is possible to efficiently perform signal transmission between the column signal processor 112 and the second signal processor 92 by the first coupling section 71.

As illustrated in FIG. 7B, the second coupling section 72 is provided between the first signal processor 91 and the interface section 90 in plan view. At least a portion of the first signal processor 91 is provided between the first coupling section 71 and the second coupling section 72. The second coupling section 72 is provided on side opposite to the first coupling section 71 with respect to the first signal processor 91.

In addition, as illustrated in FIG. 7C, the second coupling section 72 is provided on side opposite to the first coupling section 71 with respect to the third signal processor 93. Accordingly, in the imaging element 1 according to the present embodiment, it is possible to efficiently perform signal transmission between the circuit of the second substrate 102 and the circuit of the third substrate 103 by the second coupling section 72. In the imaging element 1, it is possible to efficiently perform signal transmission between the first signal processor 91 and the third signal processor 93, signal transmission between the third signal processor 93 and the interface section 90, and the like.

FIGS. 8 and 9 are diagrams for description of an example of signal transmission in the imaging element according to the embodiment. The imaging element 1 according to the embodiment may perform first mode signal transmission and second mode signal transmission. FIG. 8 illustrates the first mode signal transmission, and FIG. 9 illustrates the second mode signal transmission. The first mode signal transmission is a mode in which signal transmission is performed with use of a multi-cycle, that is, a multi-cycle path type signal transmission. The second mode signal transmission is a mode in which signal transmission is performed with use of serial/parallel conversion and parallel/ serial conversion, and is serial/parallel-parallel/serial conversion type signal transmission.

In the present embodiment, the first coupling section 71 is configured to be able to perform the first mode signal transmission. The first coupling section 71 may perform signal transmission between the second substate 102 and the third substrate 103 by the first mode signal transmission. In addition, the second coupling section 72 is configured to be able to perform the second mode signal transmission. The second coupling section 72a and the second coupling section 72b may each perform signal transmission between the second substrate 102 and the third substrate 103 by the second mode signal transmission.

In an example illustrated in FIG. 8, the first output section 51 of the first coupling section 71 includes a flip-flop C11. The first input section 52 of the first coupling section 71 includes a flip-flop C12. A data signal having a frequency f1 is inputted from a flip-flop C10 of the column signal processor 112 to the flip-flop C11. The signal level of this data signal makes a transition (changes) once every plurality of transitions, e.g., once every four transitions of a clock signal as a reference.

The flip-flop C11 samples a data signal from the flip-flop C10 in synchronization with a clock signal having a frequency f2 (=f1/4), and outputs the data signal to the first input section 52. A data signal having the frequency f2 is inputted from the first output section 51 to the flip-flop C12 of the first input section 52 through the coupling electrode 40. The flip-flop C12 samples the data signal from the flip-flop C11 in synchronization with the clock signal having the frequency f2, and outputs the data signal to a circuit (e.g., a flip-flop C20 of the second signal processor 92) outside the first coupling section 71.

The data signal having the frequency f2 is inputted from the first input section 52 to the flip-flop C20 of the second signal processor 92. The flip-flop C20 may sample the data signal from the flip-flop C12 in synchronization with a clock signal having a frequency f1′, and capture and hold the data signal.

Thus, in the first coupling section 71, transmission of the data signal is performed in synchronization with the clock signal having the frequency f2 lower than the frequency f1 (e.g., a frequency equal to one-fourth of the frequency f1). This makes it possible to suppress transmission and reception of an erroneous data signal between layers of the second substrate 102 and the third substrate 103 and correctly transmit and receive a signal. In the example illustrated in FIG. 8, in the imaging element 1, it is possible to appropriately transmit the signal of each of the pixels from the column signal processor 112 to the second signal processor 92.

In an example illustrated in FIG. 9, the second output section 61 of the second coupling section 72 includes a serial/parallel converter 65 and a plurality of flip-flops C21. The second input section 62 of the second coupling section 72 includes a plurality of flip-flops C22 and a parallel/serial converter 66. The serial/parallel converter 65 includes a serial/parallel conversion circuit (deserializer), and is configured to be able to convert a serial signal into a parallel signal. The parallel/serial converter 66 includes a parallel/serial conversion circuit (serializer), and is configured to be able to convert a parallel signal into a serial signal. It is to be noted that the serial/parallel converter 65 and the parallel/serial converter 66 may be provided outside the second coupling section 72.

The data signal having the frequency f1 is inputted from a circuit (e.g., a flip-flop C15 of the first signal processor 91) outside the second coupling section 72 to the serial/parallel converter 65. The serial/parallel converter 65 converts the data signal that is a serial signal inputted from the flip-flop C15 into a parallel signal, and outputs the parallel signal to each of the flip-flops C21. The flip-flops C21 each output the data signal from the serial/parallel converter 65 to the second input section 62 in synchronization with the clock signal having the frequency f2 (=f1/4).

The data signal that is a parallel signal is inputted from the second output section 61 to the plurality of flip-flop C22 of the second input section 62 through the coupling electrode 40. The flip-flops C22 each samples the data signal from the flip-flop C21 in synchronization with the clock signal having the frequency f2, and outputs the data signal to the parallel/serial converter 66.

The data signal having the frequency f2 is inputted to the parallel/serial converter 66. The parallel/serial converter 66 converts the data signals that are parallel signals inputted from the plurality of flip-flops C22 into serial signals, and outputs the data signals to a circuit (e.g., a flip-flop C25 of the third signal processor 93) outside the second coupling section 72. The flip-flop C25 of the third signal processor 93 may sample the data signal from the parallel/serial converter 66 in synchronization with the clock signal having the frequency f1′, and capture and hold the data signal.

Thus, the second coupling section 72 performs transmission and reception of the data signal in synchronization with the clock signal having the frequency f2 lower than the frequency f1 by the second mode signal transmission. This makes it possible to prevent transmission and reception of an erroneous data signal between the second substrate 102 and the third substrate 103 and appropriately perform data transmission. It is possible to efficiently perform data transmission with use of serial/parallel conversion and parallel/serial conversion. In the example illustrated in FIG. 9, in the imaging element 1, it is possible to appropriately transmit the signal of each of the pixels from the first signal processor 91 to the third signal processor 93.

In the imaging element 1, it is possible to appropriately perform signal transmission between the second signal processor 92 and the interface section 90 and signal transmission between the third signal processor 93 and the interface section 90 by the second mode signal transmission in the second coupling section 72a. In addition, in the imaging element 1, it is possible to appropriately perform signal transmission between the first imaging controller 81 and the second imaging controller 82 by the second mode signal transmission in the second coupling section 72b.

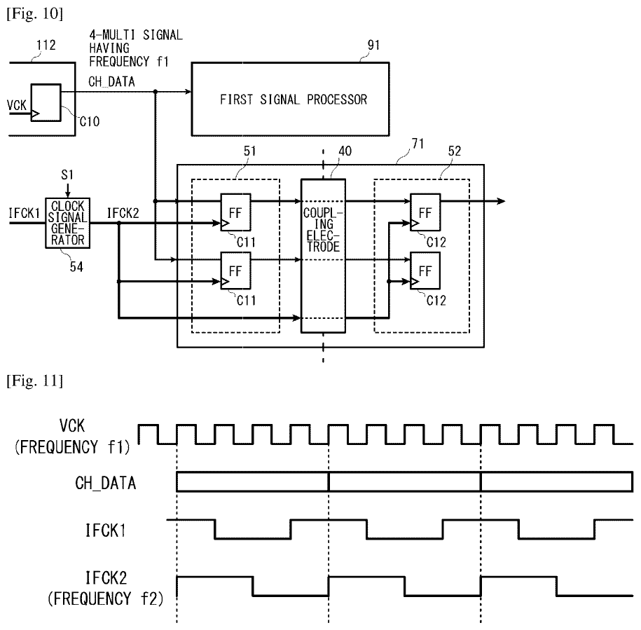

FIG. 10 is a diagram for description of a configuration example of the first coupling section of the imaging element according to the embodiment. FIG. 11 is a diagram illustrating an example of timing adjustment in the first coupling section of the imaging element according to the embodiment. In an example illustrated in FIG. 10, the imaging element 1 includes a clock signal generator 54. The flip-flop C10 of the column signal processor 112 outputs a data signal CH_DATA to the first signal processor 91 and the first coupling section 71 in synchronization with a clock signal VCK. The signal level (voltage) of the data signal CH_DATA makes a transition to a high level or a low level once every four transitions of the clock signal VCK, as illustrated in FIG. 11.

The clock signal generator 54 is configured to generate and output a clock signal. The clock signal generator 54 includes a flip-flop, an inverter, and the like. A clock signal IFCK1 is inputted to the clock signal generator 54. In addition, a signal in-dicating a transition timing (a rising edge and a falling edge) of the data signal CH_DATA is inputted as an alignment signal S1 to the clock signal generator 54.

The clock signal generator 54 changes the phase (output timing) of the clock signal IFCK1 in accordance with the alignment signal S1 (phase matching signal). The phase of the clock signal IFCK1 is adjusted in accordance with a timing of the alignment signal S1. As illustrated in FIG. 11, the clock signal generator 54 outputs a clock signal IFCK2 having the frequency f2 (=f1/4) as a phase-adjusted clock signal. It can be said that the clock signal generator 54 regenerates the clock signal IFCK2 adjusted in ac-cordance with the phase of the data signal CH_DATA. It is to be noted that the first coupling section 71 may include the clock signal generator 54.

The clock signal generator 54 supplies the clock signal IFCK2 to the first output section 51 and the first input section 52 of the first coupling section 71. The phase-adjusted clock signal IFCK2 having the frequency f2 is inputted to each of the flip-flops C11 of the first output section 51 and each of the flip-flops C12 of the first input section 52. This makes it possible for the first coupling section 71 to transmit and receive the data signal CH_DATA in accordance with the clock signal IFCK2 having the low frequency f2 by the first mode signal transmission. This makes it possible to avoid difficulty in skew timing adjustment and reduce the level of setting difficulty. It is possible to appropriately perform signal transmission between substrates.

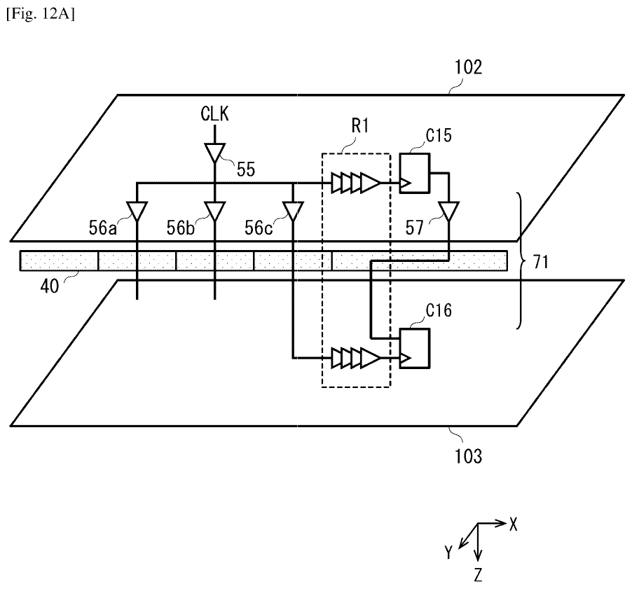

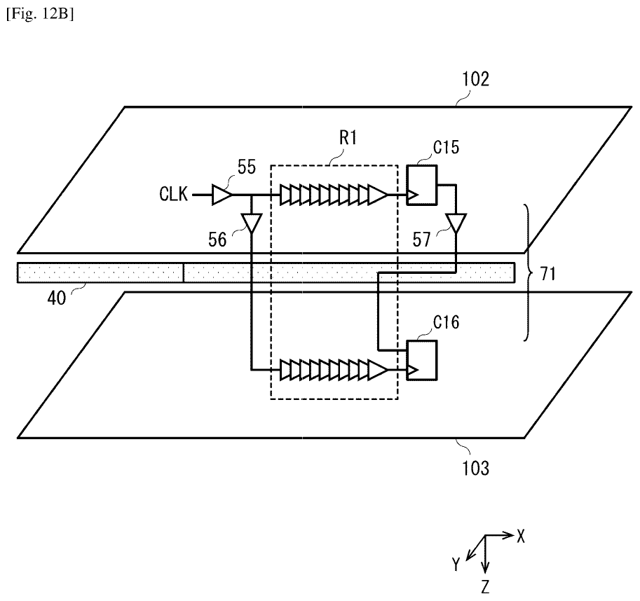

In addition, in the present embodiment, the first output section 51 and the first input section 52 of the first coupling section 71 each include a plurality of buffer circuits. FIG. 12A is a diagram illustrating a configuration example of the first coupling section of the imaging element according to the embodiment. The first coupling section 71 includes a buffer 55, a buffer 56 (buffers 56a to 56c in FIG. 12A), and a buffer 57. The buffer 55, the buffer 56, and the buffer 57 may be disposed in one or both of the first output section 51 and the first input section 52.

In an example illustrated in FIG. 12A, a plurality of buffers 56 is provided at predetermined intervals in the first coupling section 71 extending in the X-axis direction. The buffers 56 are disposed at the predetermined intervals from the position of the buffer 55 as a reference position (starting position), for example, as in the example in FIG. 12A. The buffer 55 is electrically coupled to the buffers 56a to 56c, and outputs the clock signal CLK to the buffers 56a to 56c. The buffers 56a to 56c each output the clock signal CLK inputted from the buffer 55 to the circuit of the third substrate 103.

In the imaging element 1, it is possible to branch the clock signal by the plurality of buffers 56 and transmit thus-branched signals, and it is possible to shorten a non-common portion (non-common path) of a clock signal path. This makes it possible to prevent difficulty in skew timing adjustment, and makes it possible to appropriately perform signal transmission at an interface between the second substrate 102 and the third substrate 103.

FIG. 12B is a diagram illustrating a configuration example of a first coupling section of an imaging element according to a comparative example. In the comparative example, a clock signal is transmitted by the buffer 55 and one buffer 56, and a clock signal path is not divided. In this case, as illustrated in FIG. 12B, a non-common path in a region R1 indicated by a broken line is long, and the number of buffers disposed in the region R1 is increased, which causes difficulty in skew timing adjustment.

In contrast, in the present embodiment, as illustrated in FIG. 12A, the non-common path in the region R1 is shortened by dividing the clock signal path, and the number of buffers in the region R1 is reduced. This makes it possible for a flip-flop C16 of the third substrate 103 to correctly receive a data signal inputted from the flip-flop C15 through the buffer 57 in accordance with a clock signal inputted from the buffer 56c.

### Workings and Effects

The imaging element (imaging element 1) according to the present embodiment includes a first substrate (first substrate 101) that includes a plurality of photoelectric converters (photoelectric converters 12) each configured to generate electric charge by photoelectric conversion, a second substrate (second substrate 102) that includes a first signal processor (first signal processor 91) configured to obtain a signal based on the electric charge generated by the photoelectric converter and perform signal processing, and is stacked on the first substrate, a third substrate (third substrate 103) that includes a second signal processor (second signal processor 92) configured to perform signal processing, and is staked on the second substrate, a first coupling section (first coupon section 71) provided with a plurality of first electrodes that each couples a circuit of the second substrate and a circuit of the third substrate, and a second coupling section (second coupling section 72) provided with a plurality of second electrodes that each couples the circuit of the second substrate and the circuit of the third substrate. A size of the first coupling section is different from a size of the second coupling section.

In the imaging element 1 according to the present embodiment, the first signal processor 91 and the second signal processor 92 are disposed on different substrates. In addition, the imaging element 1 includes the first coupling section 71 and the second coupling section 72 that couple the circuit of the second substrate 102 including the first signal processor 91 and the circuit of the third substrate 103 including the second signal processor 92. This makes it possible to suppress an increase in chip area, as compared with a case where the first signal processor 91 and the second signal processor 92 are disposed on the same substrate.

Next, description is given of modification examples of the present disclosure.

Hereinafter, components similar to those of the embodiment described above are denoted by the same reference numerals, and descriptions thereof are omitted as ap-propriate.

### 2. Modification Examples

### 2-1. Modification Example 1

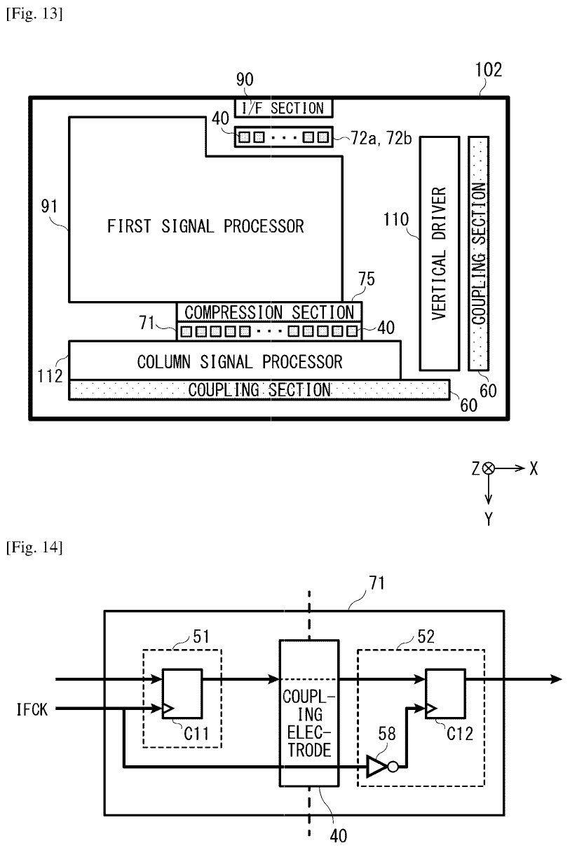

FIG. 13 is a diagram for description of a configuration example of an imaging element according to Modification Example 1. The imaging element 1 may include a compression section 75 and a decompression section 76 (not illustrated). The compression section 75 includes a compression circuit, and is configured to be able to compress a signal. The decomposition section 76 includes a decompression circuit, and is configured to be able to decompress a signal For example, as illustrated in FIG. 13, the compression section 75 is provided on the second substrate 102. The decompression section 76 is provided on the third substrate 103. In an example illustrated in FIG. 13, the compression section 75 is provided between the AD converter 20 of the column signal processor 112 and the first signal processor 91. It is to be noted that the compression section 75 may be disposed between the column signal processor 112 and the first coupling section 71.

The signal of each of the pixels converted into a digital signal is inputted from the column signal processor 112 to the compression section 75. The compression section 75 performs compression processing on the signal of each of the pixels, and outputs, to the first coupling section 71, image data including the pixel signal having been subjected to the processing. The first coupling section 71 transmits compressed image data to the circuit of the third substrate 103. The compressed image data is inputted from the first coupling section 71 to the decompression section 76 of the third substrate 103. The decompression section 76 performs decompression processing on the compressed image data, and outputs, to the second signal processor 92, image data including the pixel signal having been subjected to the processing.

In the present modification example, the signal of each of the pixels is compressed by the compression section 75, inputted to the first coupling section 71, and transmitted to the third substrate 103. This makes it possible to reduce the number of signals to be transmitted by the first coupling section 71, and reduce the number of coupling electrodes 40, the number of flip-flops, and the like in the first coupling section 71. Accordingly, as in the example illustrated in FIG. 13, it is possible to reduce the area of the first coupling section 71. Reducing the number of signals to be transmitted makes it possible to avoid difficulty in skew timing adjustment and reduce the level of setting difficulty.

### 2-2. Modification Example 2

FIG. 14 is a diagram for description of a configuration example of a first coupling section of an imaging element according to Modification Example 2. In an example illustrated in FIG. 14, the first coupling section 71 includes an inverter 58. The inverter 58 may output an inverted signal of an inputted signal. An inverted signal of the clock signal IFCK is inputted from the inverter 58 to the flip-flop C12 of the first input section 52. This makes it possible to improve a hold timing in the flip-flop C12. It is to be noted that the second coupling section 72 may be provided with an inverter for clock signal inversion. Even in the present modification example, it is possible to prevent difficulty in skew timing adjustment. It is possible to reduce the level of setting difficulty in the imaging element 1.

### 2-3. Modification Example 3

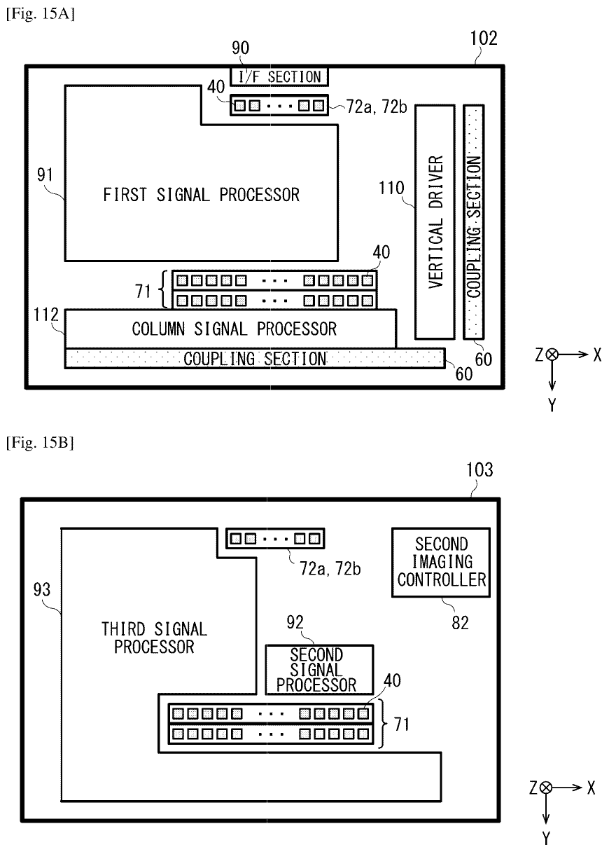

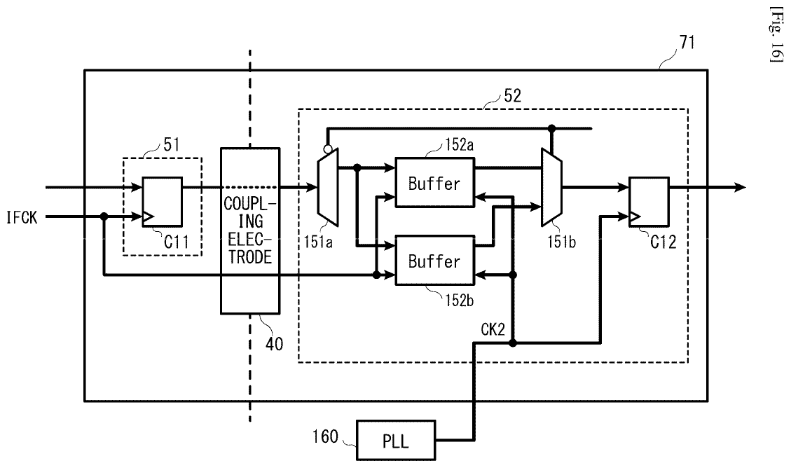

FIGS. 15A and 15B are diagrams each illustrating a layout example of an imaging element according to Modification Example 3. The layout example in FIG. 15A indicates a layout example in the second substrate 102 of the first to third substrates 101 to 103. In addition, the layout example in FIG. 15B indicates a layout example in the third substrate 103. The first coupling section 71 may be disposed dividedly in two or more stages. In the examples illustrated in FIGS. 15A and 15B, the first coupling section 71 is disposed dividedly in two stages. In the first coupling section 71, two electrode blocks each including a plurality of coupling electrodes 40 disposed side by side in the X-axis direction are disposed in the Y-axis direction. It can be said that two electrode blocks are stacked in the vertical direction.

In the present modification example, it is possible to improve flexibility in design and layout by securing space on the left and the right of the first coupling section 71. In addition, it is possible to reduce routing of signal wiring lines (such as a data signal wiring line and a clock signal wiring line) between circuits and efficiently perform signal transmission. For example, as in the example illustrated in FIG. 15B, it is possible to expand (increase) a region where the third signal processor 93 is disposed. In addition, in the example illustrated in FIG. 15B, the second signal processor 92 and the second imaging controller 82 are disposed relatively close to the second coupling section 72. This makes it possible to efficiently perform signal transmission between the second signal processor 92 and the second coupling section 72 and signal transmission between the second imaging controller 82 and the second coupling section 72.

### 2-4. Modification Example 4

FIG. 16 is a diagram for description of a configuration example of a first coupling section of an imaging element according to Modification Example 4. As in an example illustrated in FIG. 16, transmission and reception of signals between the second substrate 102 and the third substrate 103 may be performed with use of a clock signal generated by a PLL (Phase Locked Loop) 160 provided on the third substrate 103 of the imaging element 1.

The PLL 160 includes a phase synchronization circuit, and is configured to generate and output a clock signal that is a signal repeating the high level and the low level. The PLL 160 generates, for example, a clock signal CK2 having a predetermined frequency on the basis of a reference clock signal inputted from outside, and supplies the clock signal CK2 to the first coupling section 71. In the present modification example, the first input section 52 of the first coupling section 71 is provided with a plurality of asynchronous buffers 152 (asynchronous buffers 152a and 152b in FIG. 16). The asynchronous buffers 152 each are configured to be able to execute, for example, data writing and data reading asynchronously.

In the example illustrated in FIG. 16, the first input section 52 includes the asynchronous buffer 152a and the asynchronous buffer 152b. The asynchronous buffer 152a and the asynchronous buffer 152b each include, for example, an asynchronous FIFO (First In First Out) circuit. The asynchronous buffers 152a and 152b each are also referred to as an asynchronous buffer memory. In addition, the first input section 52 includes a selector 151a and a selector 151b. The selector 151a includes a selection circuit, and is configured to be able to output an inputted signal to the asynchronous buffers 152a and 152b. The selector 151b includes a selection circuit, and is configured to output, to the flip-flop C12, a signal selected from signals inputted from the asynchronous buffers 152a and 152b.

The clock signal IFCK is inputted from side of the second substrate 102 to each of the asynchronous buffer 152a and the asynchronous buffer 152b through the coupling electrode 40. In addition, the clock signal CK2 is inputted from the PLL 160 to each of the asynchronous buffers 152a and 152b. The asynchronous buffers 152a and 152b may perform writing (sampling) of a data signal from the flip-flop C11 in synchronization with the clock signal IFCK. In addition, the asynchronous buffers 152a and 152b may perform reading of a data signal to the selector 151b and the flip-flop C12 in synchronization with the clock signal CK2.

In the imaging element 1 according to the present modification example. signal transmission between the second substrate 102 and the third substrate 103 may be performed by asynchronous communication using the asynchronous buffers 152. This makes it possible to set the frequency of the clock signal CK2 to be used in the circuit (such as the second signal processor 92, the third signal processor 93, and the second imaging controller 82) of the third substrate 103 independently of the clock signal IFCK. For example, it is possible to increase the frequency of the clock signal CK2 to a frequency higher than the frequency of the clock signal IFCK. This makes it possible to increase processing speed in a logic circuit and the like of the third substrate 103.

### 2-5. Modification Example 5

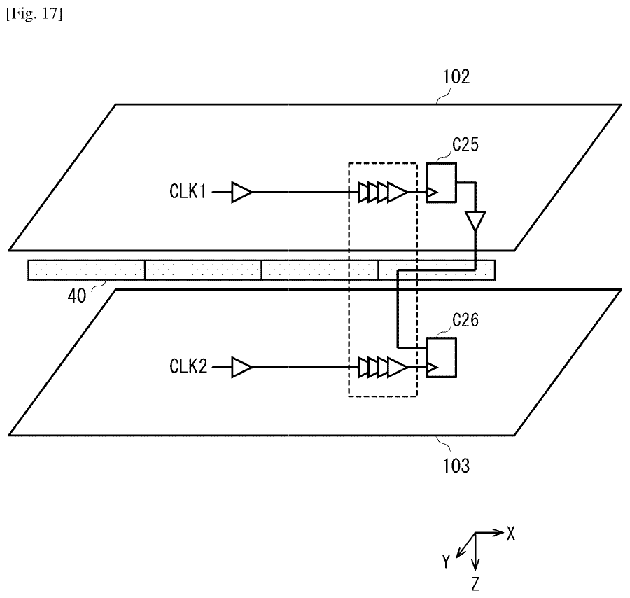

FIG. 17 is a diagram for description of a configuration example of an imaging element according to Modification example 5. The imaging element 1 is configured to be able to execute signal transmission between the second substrate 102 and the third substrate 103 by asynchronous communication. For example, one or both of the first coupling section 71 and the second coupling section 72 may have a circuit configuration schematically illustrated in FIG. 17. Using asynchronous communication makes it possible to perform skew timing adjustment relatively easily.

In an example illustrated in FIG. 17, the flip-flop C25 of the second substrate 102 outputs a data signal to the flip-flop C26 of the third substrate 103 in accordance with the clock signal CK1. The flip-flop C26 of the third substrate 103 receives the data signal inputted from the flip-flop C25 in accordance with the clock signal CK2. In the imaging element 1, for example, a signal that changes (make a transition) only once in a one-frame period may be transmitted and received by asynchronous communication. In the present modification example, it is possible to reduce the area of a circuit for synchronous communication, the number of through electrodes, and the like.

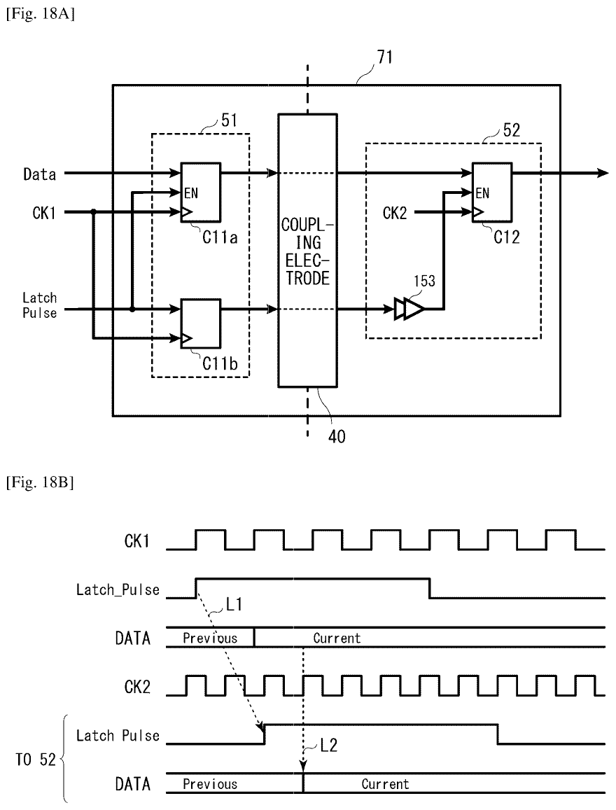

FIG. 18A is a diagram for description of a configuration example of a first coupling section of the imaging element according to Modification Example 5. FIG. 18B is a timing chart for description of an operation example of the first coupling section of the imaging element according to Modification Example 5. FIG. 18A illustrates an example in a case where the first coupling section 71 is configured to be able to execute asynchronous communication. It is to be noted that the second coupling section 72 may be configured to be able to execute asynchronous communication.

In an example in FIG. 18, the flip-flop C11b of the fist output section 51 samples a latch pulse (Latch_Pulse) in synchronization with the clock signal CK1, and outputs the latch pulse to the first input section 52 as indicated by a broken line L1 in the timing chart in FIG. 18B. The latch pulse is inputted as an enable signal to a flip-flop C11a of the first output section 51. In a case where the latch pulse is at the high level, the flip-flop C11a samples a signal Data that is a data signal in synchronization with the clock signal CK1, and outputs the signal Data to the first input section 52 as indicated by a broken line L2 in FIG. 18B.

The signal Data is inputted from the flip-flop C11a of the first output section 51 to the flip-flop C12 of the first input section 52. In addition, the latch pulse is inputted as an enable signal from a flip-flop C11b to the flip-flop C12 through a delay circuit 153. The delay circuit 153 includes, for example, a Delay buffer, and includes a flip-flop. In addition, the clock signal CK2 that is different from the clock signal CK1 is inputted to the flip-flop C12.

For example, in a case where the latch pulse is at the high level, the flip-flop C12 may sample the signal Data in synchronization with the clock signal CK2 and output the signal Data to a circuit outside the first coupling section 71. Accordingly, in the imaging element 1, it is possible to perform transmission and reception of the latch pulse and the data signal between the second substrate 102 and the third substrate 103 and perform asynchronous communication. Using asynchronous communication makes it possible to perform skew timing adjustment relatively easily.

### 3. Usage Example

The imaging element 1 and the electronic apparatus 10 described above are usable in a variety of cases of sensing light such as visible light, infrared light, ultraviolet light, and X-ray as follows.
Apparatuses that shoot images for viewing such as digital cameras or mobile apparatuses each having a camera function
Apparatuses for traffic use such as onboard sensors that shoot images of the front, back, surroundings, inside, and so on of an automobile for safe driving such as automatic stop and for recognizing a driver's state, monitoring cameras that monitor traveling vehicles and roads, or distance measurement sensors that measure vehicle-to-vehicle distance
Apparatuses for use in home electrical appliances such as televisions, refrigerators, or air-conditioners to shoot images of a user's gesture and bring the appliances into operation in accordance with the gesture
Apparatuses for medical care and health care use such as endoscopes or apparatuses that shoot images of blood vessels by receiving infrared light
Apparatuses for security use such as monitoring cameras for crime prevention or cameras for individual authentication
Apparatuses for beauty use such as skin measurement apparatuses that shoot images of skin or microscopes that shoot images of scalp
Apparatuses for sports use such as action cameras or wearable cameras for sports applications and the like
Apparatuses for agricultural use such as cameras for monitoring the conditions of fields and crops

### 4. Application Examples

The technology (the present technology) according to the present disclosure is applicable to a variety of products. For example, the imaging element 1 or the like may be applied to any of various electronic apparatuses having an imaging function such as a camera or a cellular phone. Applying the technology according to the present disclosure makes it possible to downsize the electronic apparatuses.

Although the present disclosure has been described with reference to the embodiments, the modification examples, the usage examples, and the application examples, the present disclosure is not limited to the embodiments and the like described above, and may be modified in a variety of ways. For example, the modification examples described above have been described as modification examples of the embodiment described above; however, configurations of the respective modification examples may be combined as appropriate.

The imaging element according to an embodiment of the present disclosure includes a first substrate, a second substrate, a third substrate, a first coupling section, and a second coupling section. The first substrate includes a plurality of photoelectric converters each configured to generate electric charge by photoelectric conversion. The second substrate includes a first signal processor configured to obtain a signal based on the electric charge generated by the photoelectric converter and perform signal processing, and is stacked on the first substrate. The third substrate includes a second signal processor configured to perform signal processing, and is stacked on the second substrate. The first coupling section is provided with a plurality of first electrodes that each couples a circuit of the second substrate and a circuit of the third substrate. The second coupling section is provided with a plurality of second electrodes that each couples the circuit of the second substrate and the circuit of the third substrate. A size of the first coupling section is different from a size of the second coupling section. This makes it possible to suppress an increase in chip area of the imaging element.

An electronic apparatus according to an embodiment of the present disclosure includes a first substrate, a second substrate, a third substrate, a first coupling section, and a second coupling section. The first substrate includes a plurality of photoelectric converters each configured to generate electric charge by photoelectric conversion. The second substrate includes a first signal processor configured to obtain a signal based on the electric charge generated by the photoelectric converter and perform signal processing, and is stacked on the first substrate. The third substrate includes a second signal processor configured to perform signal processing, and is stacked on the second substrate. The first coupling section is provided with a plurality of first electrodes that each couples a circuit of the second substrate and a circuit of the third substrate. The second coupling section is provided with a plurality of second electrodes that each couples the circuit of the second substrate and the circuit of the third substrate. A size of the first coupling section is different from a size of the second coupling section. This makes it possible to achieve an electronic apparatus that makes it possible to suppress an increase in chip area.

It is to be noted that the effects described herein are merely exemplary and are not limited to the description, and may further include other effects. In addition, the present disclosure may also have the following configurations.

(1)

A light detecting device comprising:
a first substrate including a plurality of photoelectric converters, the plurality of photoelectric converters configured to generate electric charges by photoelectric conversion;
a second substrate including a first signal processor configured to perform first signal processing to generate a signal based on the electric charges generated by the plurality of photoelectric converters, the second substrate stacked on the first substrate; a third substrate including a second signal processor configured to perform second signal processing, the third substrate stacked on the second substrate; a first coupling section including a plurality of first electrodes, the plurality of first electrodes coupling circuitry of the second substrate and circuitry of the third substrate; and
a second coupling section including a plurality of second electrodes, the plurality of second electrodes coupling the circuitry of the second substrate and circuitry of the third substrate,
an area of the first coupling section being different from an area of the second coupling section in a plan view.
   (2)

The light detecting device according to (1), wherein the plurality of photoelectric converters is arranged on the first substrate in a first direction and a second direction orthogonal to the first direction.

(3)

The light detecting device according to (1) or (2), wherein
the plurality of first electrodes is arranged side by side in a first direction, and
the plurality of second electrodes is arranged side by side in the first direction.
   (4)

The light detecting device according to any one of (1) to (3), wherein a length of the first coupling section in the first direction is different from a length of the second coupling section in the first direction.

(5)

The light detecting device according to any one of (1) to (4), wherein at least a portion of the first signal processor is arranged between the first coupling section and the second coupling section in the plan view.

(6)

The light detecting device according to any one of (1) to (5), wherein
the first substrate includes a plurality of pixels, each pixel of the plurality of pixels including a photoelectric converter of the plurality of photoelectric converters and configured to output an analog signal based on the electric charges generated by photo-electric conversion, and
the second substrate includes an analog-digital converter configured to convert the analog signal outputted from the pixel into a digital signal.
   (7)

The light detecting device according to any one of (1) to (6), wherein
the first signal processor is configured to perform the first signal processing to generate a first digital signal based on the electric charges generated by the plurality of photo-electric converters, and
the second signal processor is configured to perform the second signal processing to generate a second digital signal based on a signal from the first coupling section, the signal based on the electric charges generated by the plurality of photoelectric converters.
   (8)

The light detecting device according to (6), wherein the first coupling section is arranged between the analog-digital converter and the first signal processor in the plan view.

(9)

The light detecting device according to any one of (1) to (7), wherein the second coupling section is arranged on side opposite to the first coupling section with respect to the first signal processor in the plan view.

(10)

The light detecting device according to any one of (1) to (9), wherein
the plurality of first electrodes is arranged in two or more rows.
   (11)

The light detecting device according to any one of (1) to (10), further comprising:
a compression section arranged on the second substrate and configured to compress a signal; and
a decompression section arranged on the third substrate and configured to decompress the compressed signal,
wherein the first coupling section is configured to transmit the compressed signal compressed by the compression section to the decompression section.
   (12)

The light detecting device according to (11), wherein the compression section is arranged between the analog-digital converter and the first signal processor.

(13)

The light detecting device according to any one of (1) to (12), further comprising:
a third signal processor arranged on the third substrate,
wherein the third signal processor is configured to perform third signal processing to generate a third digital signal based on the electric charges generated by the plurality of photoelectric converters through the second coupling section.
   (14)

The light detecting device according to (13), wherein the third signal processor is configured to perform recognition processing on a basis of the third digital signal.

(15)

The light detecting device according to (13) or (14), wherein the first coupling section is arranged between the second signal processor and the third signal processor in the plan view.

(16)

The light detecting device according to any one of (13) to (15), wherein the second coupling section is arranged on a side opposite to the first coupling section with respect to the third signal processor in the plan view.

(17)

The light detecting device according to any one of (1) to (16), wherein the second coupling section includes at least one of a first converter or a second converter, the first converter configured to convert a serial signal into a parallel signal, and the second converter configured to convert a parallel signal into a serial signal.

(18)

The light detecting device according to any one of (1) to (17), further comprising:
an interface section, the interface section arranged on the second substrate and configured to output from the light detecting device at least one of a signal outputted from the first signal processor or a signal outputted from the second signal processor, wherein the second coupling section is arranged between the first signal processor and the interface section in the plan view.
   (19)

The light detecting device according to any one of (1) to (18), wherein each first electrode of the plurality of first electrodes and each second electrode of the plurality of second electrodes includes a through electrode, a first junction electrode, and a second junction electrode, the through electrode penetrating through the second substrate, the first junction electrode being coupled to the through electrode, and the second junction electrode being coupled to the first junction electrode.

(20)

An electronic apparatus comprising:
a first substrate including a plurality of photoelectric converters, the plurality of photo-electric converters configured to generate electric charges by photoelectric conversion;
a second substrate including a first signal processor configured to perform first signal processing to generate a signal based on the electric charges generated by the plurality of photoelectric converters, is the second substrate stacked on the first substrate;
a third substrate including a second signal processor configured to perform second signal processing, the third substrate stacked on the second substrate;
a first coupling section including a plurality of first electrodes, the plurality of first electrodes coupling circuitry of the second substrate and circuitry of the third substrate; and
a second coupling section including a plurality of second electrodes, the plurality of second electrodes coupling the circuitry of the second substrate and circuitry of the third substrate,
an area of the first coupling section being different from an area of the second coupling section in a plan view.

It should be understood by those skilled in the art that various modifications, combinations, sub-combinations, and alterations may occur depending on design requirements and other factors insofar as they are within the scope of the appended claims or the equivalents thereof.

### REFERENCE SIGNS LIST

1 imaging element
10 electronic apparatus
12 photoelectric converter
71 first coupling section
72 second coupling section
91 first signal processor
92 second signal processor
93 third signal processor
101 first substrate
102 second substrate
103 third substrate

1. A light detecting device comprising:
a first substrate including a plurality of photoelectric converters, the plurality of photoelectric converters configured to generate electric charges by photoelectric conversion;
a second substrate including a first signal processor configured to perform first signal processing to generate a signal based on the electric charges generated by the plurality of photoelectric converters, the second substrate stacked on the first substrate;
a third substrate including a second signal processor configured to perform second signal processing, the third substrate stacked on the second substrate;
a first coupling section including a plurality of first electrodes, the plurality of first electrodes coupling circuitry of the second substrate and circuitry of the third substrate; and
a second coupling section including a plurality of second electrodes, the plurality of second electrodes coupling the circuitry of the second substrate and circuitry of the third substrate,
an area of the first coupling section being different from an area of the second coupling section in a plan view.

2. The light detecting device according to claim 1, wherein the plurality of photoelectric converters is arranged on the first substrate in a first direction and a second direction orthogonal to the first direction.

3. The light detecting device according to claim 1, wherein
the plurality of first electrodes is arranged side by side in a first direction, and
the plurality of second electrodes is arranged side by side in the first direction.

4. The light detecting device according to claim 3, wherein a length of the first coupling section in the first direction is different from a length of the second coupling section in the first direction.

5. The light detecting device according to claim 1, wherein at least a portion of the first signal processor is arranged between the first coupling section and the second coupling section in the plan view.

6. The light detecting device according to claim 1, wherein
the first substrate includes a plurality of pixels, each pixel of the plurality of pixels including a photoelectric converter of the plurality of photoelectric converters and configured to output an analog signal based on the electric charges generated by photoelectric conversion, and
the second substrate includes an analog-digital converter configured to convert the analog signal outputted from the pixel into a digital signal.

7. The light detecting device according to claim 6, wherein
the first signal processor is configured to perform the first signal processing to generate a first digital signal based on the electric charges generated by the plurality of photoelectric converters, and
the second signal processor is configured to perform the second signal processing to generate a second digital signal based on a signal from the first coupling section, the signal based on the electric charges generated by the plurality of photoelectric converters.

8. The light detecting device according to claim 6, wherein the first coupling section is arranged between the analog-digital converter and the first signal processor in the plan view.

9. The light detecting device according to claim 8, wherein the second coupling section is arranged on side opposite to the first coupling section with respect to the first signal processor in the plan view.

10. The light detecting device according to claim 3, wherein
the plurality of first electrodes is arranged in two or more rows.

11. The light detecting device according to claim 6, further comprising:
a compression section arranged on the second substrate and configured to compress a signal; and
a decompression section arranged on the third substrate and configured to decompress the compressed signal,
wherein the first coupling section is configured to transmit the compressed signal compressed by the compression section to the decompression section.

12. The light detecting device according to claim 11, wherein the compression section is arranged between the analog-digital converter and the first signal processor.

13. The light detecting device according to claim 1, further comprising:
a third signal processor arranged on the third substrate,
wherein the third signal processor is configured to perform third signal processing to generate a third digital signal based on the electric charges generated by the plurality of photoelectric converters through the second coupling section.

14. The light detecting device according to claim 13, wherein the third signal processor is configured to perform recognition processing on a basis of the third digital signal.

15. The light detecting device according to claim 13, wherein the first coupling section is arranged between the second signal processor and the third signal processor in the plan view.

16. The light detecting device according to claim 13, wherein the second coupling section is arranged on a side opposite to the first coupling section with respect to the third signal processor in the plan view.

17. The light detecting device according to claim 1, wherein the second coupling section includes at least one of a first converter or a second converter, the first converter configured to convert a serial signal into a parallel signal, and the second converter configured to convert a parallel signal into a serial signal.

18. The light detecting device according to claim 1, further comprising:
an interface section, the interface section arranged on the second substrate and configured to output from the light detecting device at least one of a signal outputted from the first signal processor or a signal outputted from the second signal processor,
wherein the second coupling section is arranged between the first signal processor and the interface section in the plan view.

19. The light detecting device according to claim 1, wherein each first electrode of the plurality of first electrodes and each second electrode of the plurality of second electrodes includes a through electrode, a first junction electrode, and a second junction electrode, the through electrode penetrating through the second substrate, the first junction electrode being coupled to the through electrode, and the second junction electrode being coupled to the first junction electrode.

20. An electronic apparatus comprising:
a first substrate including a plurality of photoelectric converters, the plurality of photoelectric converters configured to generate electric charges by photoelectric conversion;
a second substrate including a first signal processor configured to perform first signal processing to generate a signal based on the electric charges generated by the plurality of photoelectric converters, is the second substrate stacked on the first substrate;
a third substrate including a second signal processor configured to perform second signal processing, the third substrate stacked on the second substrate;
a first coupling section including a plurality of first electrodes, the plurality of first electrodes coupling circuitry of the second substrate and circuitry of the third substrate; and
a second coupling section including a plurality of second electrodes, the plurality of second electrodes coupling the circuitry of the second substrate and circuitry of the third substrate,
an area of the first coupling section being different from an area of the second coupling section in a plan view.
